(19) United States
(12) Patent Application Publication
(10) Pub. No.: US 2018/0166804 A1
(43) Pub. Date: Jun. 14, 2018

(54) MULTI-LEVEL MOUNTING RAILS FOR CONTROL PANEL

(71) Applicants: Olivier Lessard Fontaine, Vancouver (CA); Geoffrey F. Crocker, Vancouver (CA); Pegah Maghsoud, West Vancouver (CA)

(72) Inventors: Olivier Lessard Fontaine, Vancouver (CA); Geoffrey F. Crocker, Vancouver (CA); Pegah Maghsoud, West Vancouver (CA)

(21) Appl. No.: 15/819,795

(22) Filed: Nov. 21, 2017

Related U.S. Application Data
(63) Continuation of application No. 62/425,541, filed on Nov. 22, 2016.

(51) Int. Cl. H01R 9/26; H02B 1/052; H05K 7/16

(52) U.S. Cl. CPC H01R 9/2608; H05K 7/16; H02B 1/0523

(57) ABSTRACT

Provided is a support structure configured for the attachment of a secondary, supported standardized mounting rail such as a DIN rail in spaced-apart relationship above a primary, supporting standardized mounting rail (e.g. a DIN rail) within an industrial enclosure such as a control panel. The support structure is connected directly to the primary, supporting standardized mounting rail, and may be applied either at the time of design/installation of the panel or at a later date, thereby enabling a highly effective and valuable expansion opportunity.

### BACKGROUND

The progression of industrial equipment is increasingly reliant upon electrical equipment to provide system information and control. At the same time, industry demands smaller and more cost effective solutions to provide these functions.

A traditional method of populating and connecting industrial electrical equipment is to arrange and mount the various required electrical components (e.g. terminal blocks, relays, circuit breakers, contactors, remote I/O, power supplies, etc.) in logical groupings on one or more standardized mounting rails (e.g. DIN rails) within an industrial enclosure, such as a control panel, which protects the electrical components from the surrounding environment whilst also protecting passers-by from the electrical components. Pathways or ducts for associated wiring are also typically provided in proximity to each standardized mounting rail for routing cables to and from the electrical components that are mounted thereon. This creates a layout that is easy to view, understand and service.

Standardized mounting rails come in a variety of sizes and cross-sectional patterns that are set by a handful of international standards organizations (e.g. the International Standards Organization, or “ISO”), and their use in industrial control panels ensures dimensional uniformity for the mounting of electrical components regardless of their manufacturer, thereby giving the end user the freedom to specify desired electrical components without concern for being committed to a single supplier due to a proprietary mounting configuration. Among the most commonly used worldwide standards for industrial electrical equipment is “DIN”, which is an acronym for “Deutsches Institut fur Normung” or “German Institute for Standardization”. DIN rail is available in several different patterns, including TS-32, TS-35, and TS-15.

In a typical industrial control panel, the standardized mounting rails are arranged and affixed in rows or columns along one interior surface (usually the bottom interior surface) of the panel, and the side walls and cover of the panel are dimensioned so as to accommodate the largest electrical components required to be housed, and to provide access as well as sufficient air space to dissipate heat generated by the electrical components during use. The exterior dimensions of the control panel may also be standardized so as to facilitate the racking or stacking of multiple control panels.

As the amount of electrical equipment that is required to provide increasingly sophisticated system information and control increases, the footprint and/or quantity of the control panels used to house and protect the electrical equipment must also increase. However, control panels having unusually large footprints quickly become unwieldy to handle (and may not fit within the area in which they are intended to be secured), and the racking or stacking of multiple control panels reduces accessibility to (and the ability to easily view) the various electrical components housed therein.

### SUMMARY

In embodiments of the presently disclosed subject matter, there is provided a support structure configured for the attachment of a secondary, supported standardized mounting rail (such as a DIN rail) in spaced-apart relationship above a primary, supporting standardized mounting rail (e.g. DIN rail) within an industrial enclosure such as a control panel. The support structure is connected directly to the primary, supporting standardized mounting rail (which rail has in turn already been affixed during panel construction along an interior surface of the control panel, or onto a plate installed within the control panel as may be required to conform with certain electrical code regulations), and may be applied either at the time of design/installation of the panel or at a later date, thereby enabling a highly effective and valuable expansion opportunity.

The support structure may comprise a single rail mount in cases where only relatively small and/or light piece(s) of additional electrical equipment are required to be supported upon the secondary, supported DIN rail, but in most cases the support structure will comprise a plurality of rail mounts, with each rail mount connecting the supporting and supported DIN rails (either directly or via an intermediate structure such as a support platform, as discussed in further detail below) at spaced-apart positions along the rails' respective lengths. For example, in cases where a supported DIN rail is the same length or shorter than a supporting DIN rail, rail mounts may be positioned along the length of the supporting DIN rail so as to generally correspond with each end of the supported DIN rail, and one or more supplemental rail mounts may be located at intermediate positions to provide additional strength if needed to bear the weight (as well as any anticipated axial loads) of the electrical equipment to be located on the supported DIN rail.

The support structure is configured and dimensioned so as to hold the supported DIN rail a sufficient height above the supporting DIN rail as needed to provide adequate component clearance to address physical space, electrical isolation and thermal management requirements within the control panel. In cases where additional lateral stability may be required, the rail mounts may further comprise one or more support legs that may be extended into contact with the interior surface of the control panel adjacent to the supporting DIN rail.

Additionally or alternatively, the support structure may be connected to a plurality of adjacent supporting DIN rails, and may support one or more supported DIN rails in an orientation that is the same as or different from that of the supporting DIN rails. By way of example, a support structure may comprise rail mounts connected to two adjacent supporting DIN rails and support a single supported DIN rail in an orientation that is essentially parallel to that of the adjacent supporting DIN rails. In another example, a support structure may comprise rail mounts connected to three adjacent supporting DIN rails and support a single supported DIN rail in an orientation that is essentially perpendicular to that of the adjacent supporting DIN rails. In yet a further example, a support structure may comprise rail mounts connected to two adjacent supporting DIN rails and support three supported DIN rails in an orientation that is essentially perpendicular to that of the adjacent supporting DIN rails. Other examples, including those in which a support structure that maintains the supported DIN rail(s) in an orientation that is somewhere between parallel and perpendicular to the supporting DIN rail(s) are of course also possible, and may be desirable when accommodating unusually-shaped electronic components on either or both of the supporting and supported DIN rails.

The rail mounts may be releasably or permanently affixed to the supporting DIN rail, and may be laterally expandable (in an orientation generally perpendicular to the elongate length of the supporting DIN rail) or longitudinally expandable (in an orientation generally parallel to the elongate length of the supporting DIN rail) in order to facilitate installation thereof onto a pre-installed supporting DIN rail. In other embodiments, snap-fit rail mounts and non-expandable rail mounts that are configured for sliding engagement with the supporting DIN rail are also contemplated. Any of the foregoing general types of rail mounts may be substituted and/or used in combination with one another. In one laterally-expandable embodiment, each rail mount comprises opposing hook elements configured for engagement with opposite lateral sides of a supporting DIN rail, and cooperating slide plates and fasteners for locking the rail mount into an engaged position on the supporting DIN rail. In one longitudinally expandable embodiment, opposing hook elements are configured for engagement with opposite lateral sides of a supporting DIN rail, and for mating engagement with one another. The opposing hook elements of this embodiment are identically configured, and each comprise a flange portion and a corresponding recess, such that the flange of a first hook element fits within the recess of the second hook element, and vice versa in mirror image, when the rail mount is engaged over a supporting DIN rail.

The supported DIN rail may itself be releasably affixed to the rail mounts with removable fasteners such as screws in order to provide access to the electrical components affixed to the supporting DIN rail below without requiring removal of the rail mounts from the supporting DIN rail. In some embodiments, the support structure may further comprise a supported platform situated between the rail mounts and the supported DIN rail. In addition to being suitably configured for the mounting of the supported DIN rail, the supported platform may comprise one or more flange portions to permit the mounting of associated wiring ducts of the sort that are typically provided in conventional control panels.

The supported platform may be held in place on the rail mounts with removable fasteners such as screws to allow the platform (including the supported DIN rail and any electrical components affixed thereto) to be lifted up and out of the way when the fasteners are removed, thereby providing access to the electrical components affixed to the supporting DIN rail below without requiring removal of the rail mounts from the supporting rail. In some embodiments of this sort, the platform may also comprise a clip structure along one or more edges thereof to permit the platform to be temporarily secured to the side wall of the control panel and/or to a rail mount of the support structure. In other embodiments, the support structure may comprise one or more rail mounts permanently affixed to a supported platform, and access to the supporting DIN rail(s) in embodiments of this sort may be enabled by releasable connection of the rail mounts to the supporting DIN rail(s).

In other embodiments, the supported platform comprises a hinge to enable the platform (including the supported DIN rail and any electrical components affixed thereto) to be pivoted up relative to the supporting DIN rail and provide access to the supporting DIN rail below. In alternate embodiments, the axis of rotation of the hinge may be either generally parallel or perpendicular to the elongate length of the DIN rails, and releasable fasteners may be utilized to better secure the supported DIN rail when the hinge is in the closed position. In a typical installation, the hinge is located along a first end of the platform, and fasteners such as screws are used to releasably secure the opposite, second end of the platform to an associated rail mount when the hinge is in the closed position. Of course, the hinge may alternatively be located at an intermediate position along the length or width of the platform (such that only a portion of the platform pivots up relative to the supporting rail), and fasteners may alternatively secure the platform to an intermediate rail mount, or to a rail mount that is adjacent to the hinge.

In further embodiments, the supported platform may comprise a drawer slide mechanism to permit the platform to slide in a telescoping fashion laterally or longitudinally vis-a-vis the supporting DIN rail below. As with the hinged embodiments described above, releasable fasteners may be utilized to better secure the supported DIN rail when the slide mechanism is in a closed position. In yet further embodiments, a single rail mount of the support structure may include a pivot and be used as a pivot point to enable the platform to rotate in-plane. In addition, any of the foregoing methods of platform displacement may be used in combination where desired.

Multiple levels of supported DIN rails and/or supported platforms may also be installed onto one another, thereby permitting yet further packaging of electronic equipment within a control panel beyond what is enabled by a supporting DIN rail and a single supported DIN rail. Each additional level may be installed on the supported DIN rail below it in the same manner as is described for the various embodiments above (i.e. by attaching each upper DIN rail to the DIN rail immediately below it).

The electrical components within a control panel are typically connected to one another and to a power supply by various wiring, and wiring considerations must accordingly be taken into account to enable a supported DIN rail (whether it is associated with a supported platform or not) to be displaced to provide access to the electrical components on the supporting DIN rail below. In preferred embodiments, the electrical components located on the supported DIN rail remain fully wired when the supported DIN rail has been pivoted, slid or lifted up out of the way of the supporting DIN rail in order to permit continued active operation of the complete electrical panel to support troubleshooting. By way of example, in hinged embodiments of the sort described above, wiring bundles (preferably held together with conventional strapping) may be routed through or adjacent to the hinged end of the supported platform. In alternate embodiments, the wiring associated with the electrical components on a supported DIN rail may be releasably coupled with conventional wire connectors to the electrical components on an upper or lower level. In practical terms, such releasable connection enables one to remove the secondary (or tertiary, quaternary, etc.) level and disconnect the wires (via the connector) for service away from the control panel, or to have complete access to the components connected to the supporting rail of the base level of the panel. Of course, this would have to be done with the electrical system of the panel at least partly off-line.

### BRIEF DESCRIPTION OF THE DRAWINGS

For a fuller understanding of the nature and advantages of the disclosed subject matter, as well as the preferred modes of use thereof, reference should be made to the following detailed description, read in conjunction with the accompanying drawings. In the drawings, like reference numerals designate like or similar steps or parts.

FIG. 1 is a perspective view of a support structure in accordance with one embodiment of the presently described subject matter, showing a secondary, supported standardized mounting rail releasably attached in spaced-apart relationship above a primary, supporting standardized mounting rail within an industrial enclosure such as a control panel.

FIG. 2 is an enlarged perspective view of a rail mount of the support structure of FIG. 1.

FIGS. 3A and 3B are perspective views of a support structure in accordance with an embodiment of the presently described subject matter comprising two rail mounts connecting a supporting mounting rail and a supported mounting rail.

FIG. 4 is a perspective view of a support structure in accordance with an embodiment of the presently described subject matter comprising two rail mounts and a supported platform connecting a supporting mounting rail and a supported mounting rail.

FIG. 5 is a perspective view of a hinged support structure in accordance with an embodiment of the presently described subject matter.

FIG. 6 is a perspective view of an alternate hinged support structure in accordance with an embodiment of the presently described subject matter.

FIGS. 7A and 7B are cross-sectional side elevation views of a hinged support structure in accordance with an embodiment of the presently described subject matter, showing the hinge in the open and closed positions.

FIG. 8 is a perspective view of a drawer slide support structure in accordance with an embodiment of the presently described subject matter.

FIGS. 9A and 9B are cross-sectional side elevation views of a three-level support structure in accordance with an embodiment of the presently described subject matter.

FIG. 10 is a cross-sectional side elevation view of the three-level support structure of FIGS. 9A and 9B.

FIG. 11 is a cross-sectional side elevation view of a three-level support structure in accordance with an alternate embodiment of the presently described subject matter.

FIG. 12 is a perspective view of a hinged support structure in accordance with an embodiment of the presently described subject matter comprising four rail mounts connecting two adjacent supporting mounting rails and three supported mounting rails in a perpendicular orientation.

FIG. 13 is a perspective view of a rail mount in accordance with an embodiment of the presently described subject matter.

FIG. 14 is a partially exploded perspective view of the rail mount of FIG. 13.

FIG. 15 is a fully exploded perspective view of the rail mount of FIG. 13.

FIG. 16 is a side elevation of a rail mount in accordance with a further embodiment of the presently described subject matter.

### DETAILED DESCRIPTION OF SPECIFIC EMBODIMENTS

The following description of preferred embodiments is merely exemplary in nature and is in no way intended to limit the invention, its application, or uses. The support structure of the present invention may take form in a number of different embodiments depending upon the particular requirements of the use.

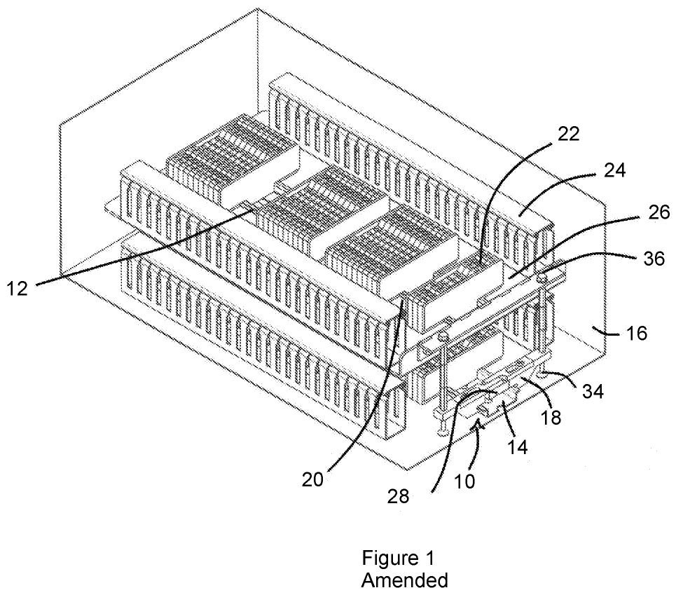

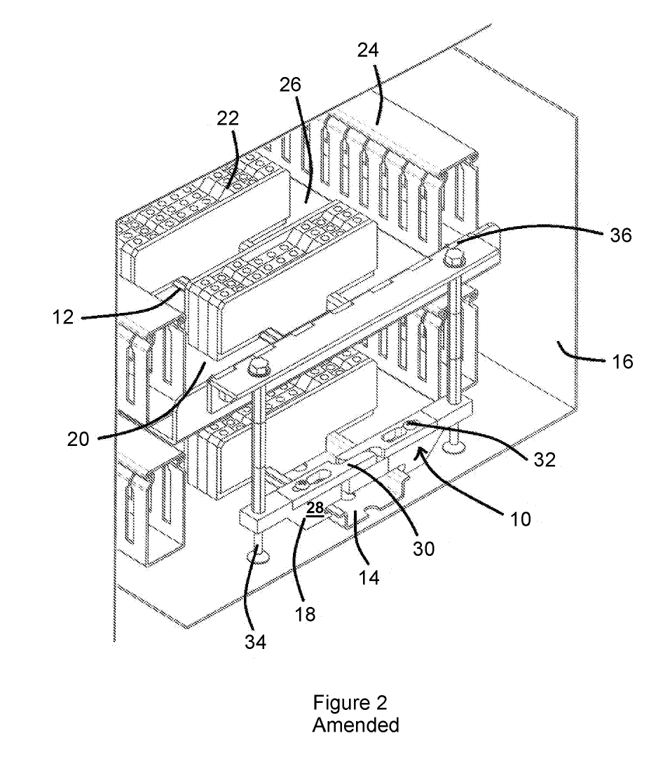

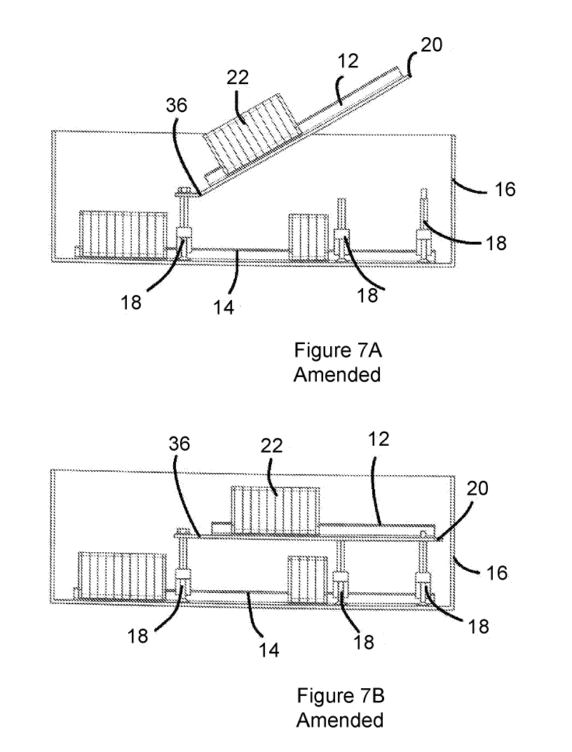

With reference to FIGS. 1 and 2, there is illustrated one embodiment of a support structure 10 configured for the releasable attachment of a supported standardized mounting rail 12 in spaced-apart relationship above a supporting standardized mounting rail 14 within an industrial enclosure such as a control panel 16. The support structure 10 is releasably connected directly to the supporting mounting rail 14, and in the embodiment shown in FIGS. 1 and 2 comprises a rail mount 18 and an elongate supported platform 20 to which the supported mounting rail 12 is affixed. Also illustrated are representative electrical components 22 affixed to supported rail 12 and supporting rail 14, and wiring ducts 24 affixed to lateral flange portions 26 of supported platform 20. Although not shown in FIG. 1, support structure 10 may comprise additional rail mounts 18 positioned along the length of the supporting rail 14 (see, for example, FIGS. 7A and 7B) to provide additional strength if required to bear the weight and any anticipated axial loads on electrical components 22 located on the supported rail 12.

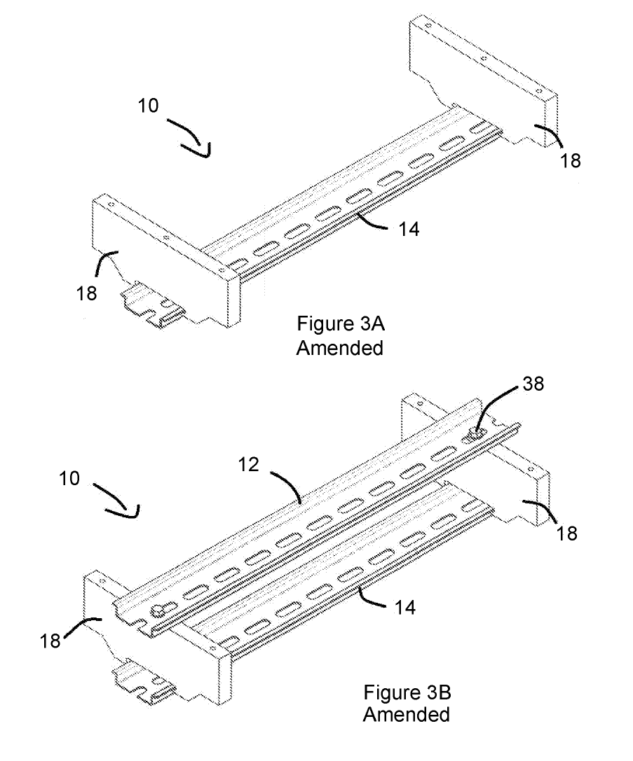

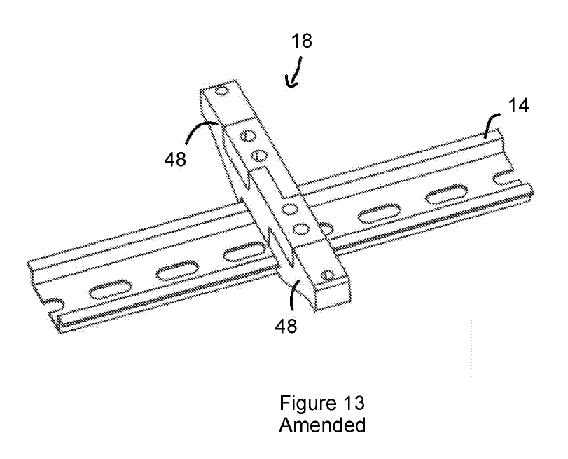

Rail mount 18 may be laterally expandable (in an orientation generally perpendicular to the elongate length of the supporting rail 14) in order to facilitate installation thereof onto a pre-installed supporting rail 14. However, as will be described in greater detail below in relation to alternate embodiments (best seen in FIGS. 3 and 13), longitudinally expandable (in an orientation generally parallel to the elongate length of the supporting rail 14) rail mounts 18, snap-fit rail mounts 18, and non-expandable rail mounts 18 that are configured for sliding engagement with supporting rail 14 are also contemplated, and may be substituted and/or used in combination with one another. In the embodiment of FIGS. 1 and 2, laterally expandable rail mount 18 comprises opposing hook elements 28 configured for engagement with opposite lateral sides of a supporting rail 14, and cooperating slide plates 30 and fasteners 32 for locking the rail mount 18 into an engaged position on the rail 14. The rail mount 18 of FIGS. 1 and 2 also includes optional support legs 34 extended into contact with panel 16 in order to provide additional stability.

Supported platform 20 of FIGS. 1 and 2 comprises a hinge 36 adjacent a first end thereof to enable pivoting of the platform 20, supported rail 12, electrical components 22, wiring ducts 24, and any associated wiring (not shown) in an upward direction relative to supporting rail 14 in order to provide access to supporting rail 14 and any electrical equipment that is installed thereupon. As will be described further below, alternate embodiments of support structure 10 that do not include a platform 20, and embodiments that are configured for sliding and/or pivoting displacement relative to supporting rail 14 are also contemplated.

FIGS. 3A and 3B illustrate an alternative embodiment of support structure 10 for releasably mounting a supported rail 12 to a supporting rail 14, and comprising two non-expandable rail mounts 18, each of which are configured for sliding engagement with supporting rail 14. In this embodiment, supported rail 12 is releasably mounted directly to the rail mounts 18 with screw fasteners 38. Although non-expandable rail mounts 18 are illustrated in FIG. 3, laterally- expandable and/or snap-fit rail mounts 18 may be substituted or combined in this embodiment, as well as in the embodiments illustrated in the other Figures.

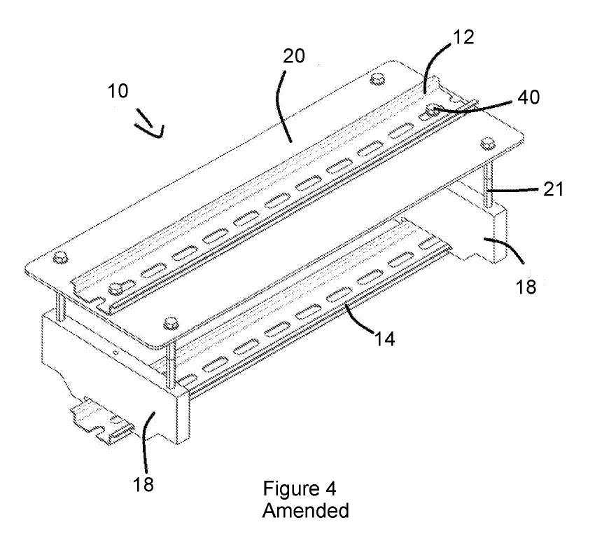

FIG. 4 illustrates a further alternative embodiment of support structure 10 for releasably mounting a supported rail 12 to a supporting rail 14. In this embodiment, support structure 10 comprises two non-expandable rail mounts 18 and a supported platform 20 to which supported rail 12 is releasably mounted with screw fasteners 40. The supported platform 20 of this embodiment is releasably connected to rail mounts 18 via extensions 21.

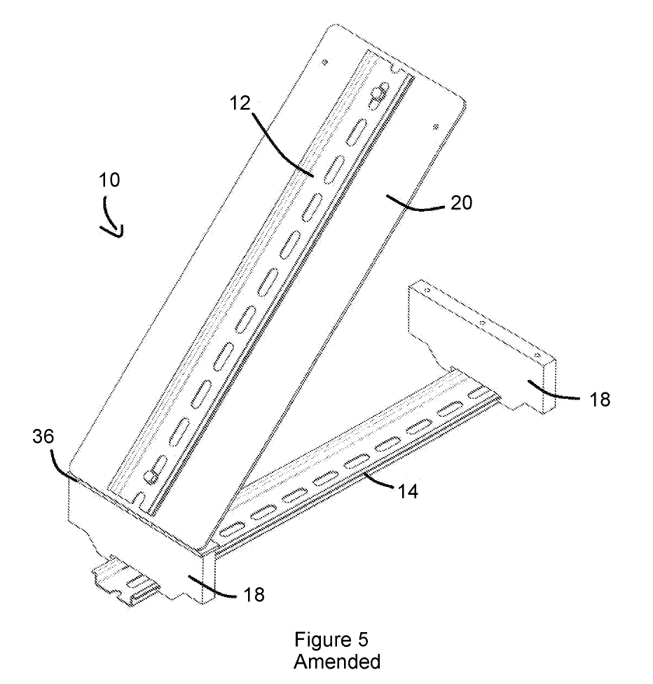

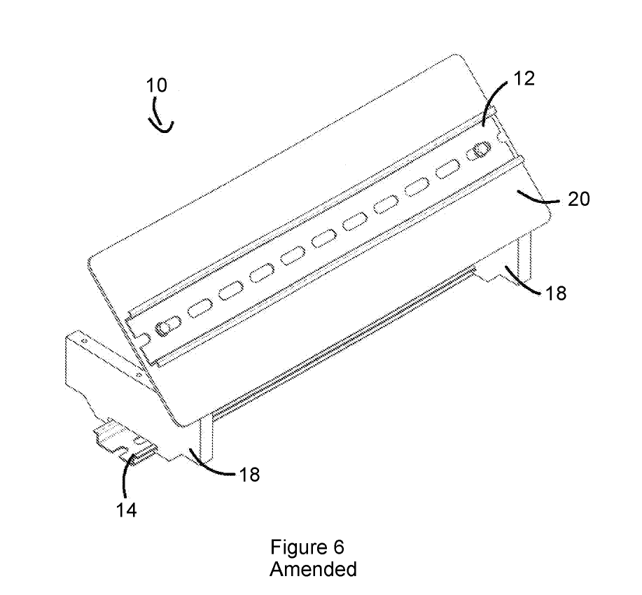

FIGS. 5-7 illustrate further alternative embodiments of support structure 10 in which the support structure 10 comprises two rail mounts 18 and a supported platform 20, and in which support structure 10 comprises a hinge 36 to enable the platform 20 (including the supported rail 12 and any electrical components 22 affixed thereto) to be pivoted up relative to the supporting rail 14 and provide access thereto. In the embodiment of FIGS. 5 and 7, the axis of rotation of the hinge 22 is generally perpendicular to the elongate length of the supporting rail 14, and in the embodiment of FIG. 6 the axis of rotation is generally parallel to the elongate length of the supporting rail 14. In a typical installation, the hinge 36 is located along a first end of the platform 20, and fasteners such as screws (not shown) are used to releasably secure the opposite, second end of the platform 20 to an associated rail mount when the hinge is in the closed position. The hinge 36 may alternatively be located at an intermediate position along the length or width of the platform 20 such that only a portion of the platform pivots up relative to the supporting rail, and fasteners may alternatively secure the platform 20 to an intermediate rail mount or to a rail mount that is adjacent to the hinge 36.

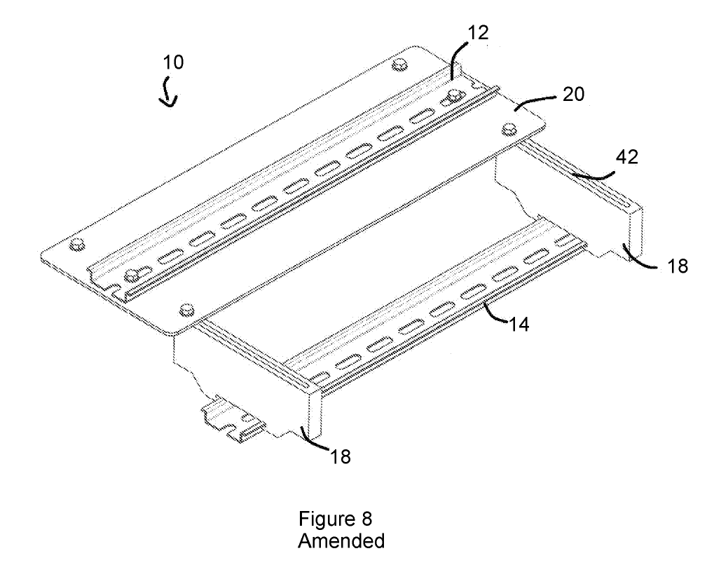

FIG. 8 illustrates further alternative embodiment of support structure 10 in which the support structure 10 comprises two rail mounts 18 and a supported platform 20, and in which supported platform 20 comprises a drawer slide mechanism 42 to permit the platform 20 to slide in a telescoping fashion vis-a-vis the supporting rail 14 below. As illustrated, platform 20 is configured for lateral displacement relative to the supporting rail 14; however, alternative embodiments configured for longitudinal displacement are also contemplated. As with the hinged embodiments described above, releasable fasteners (not shown) may be utilized to better secure the supported rail 12 when the slide mechanism 42 is in a closed position.

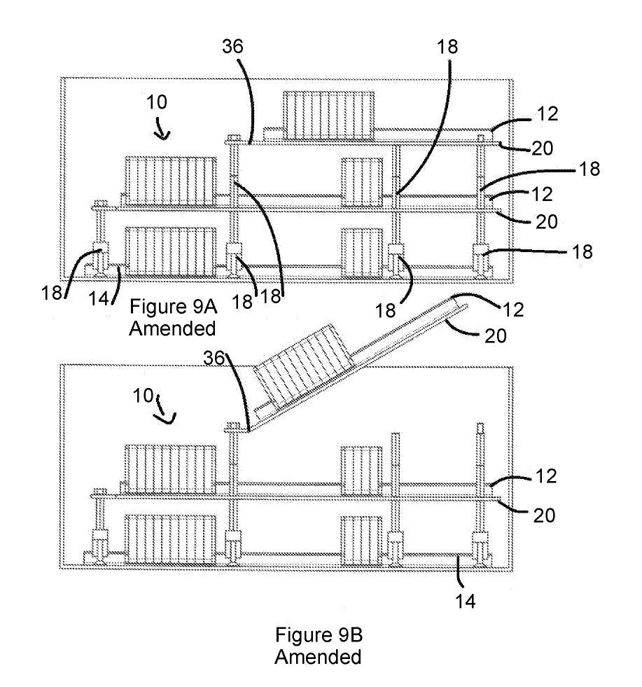

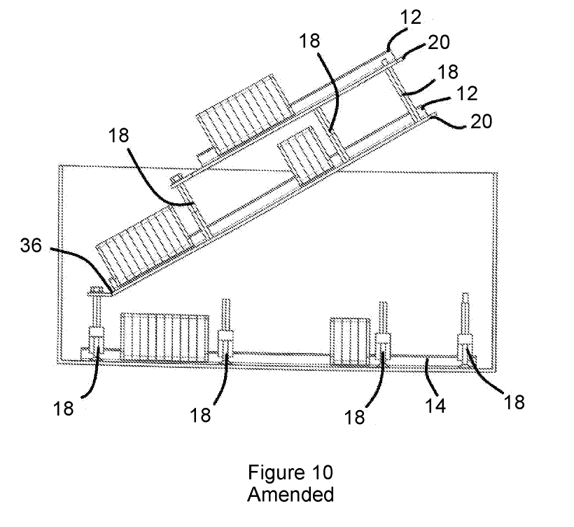

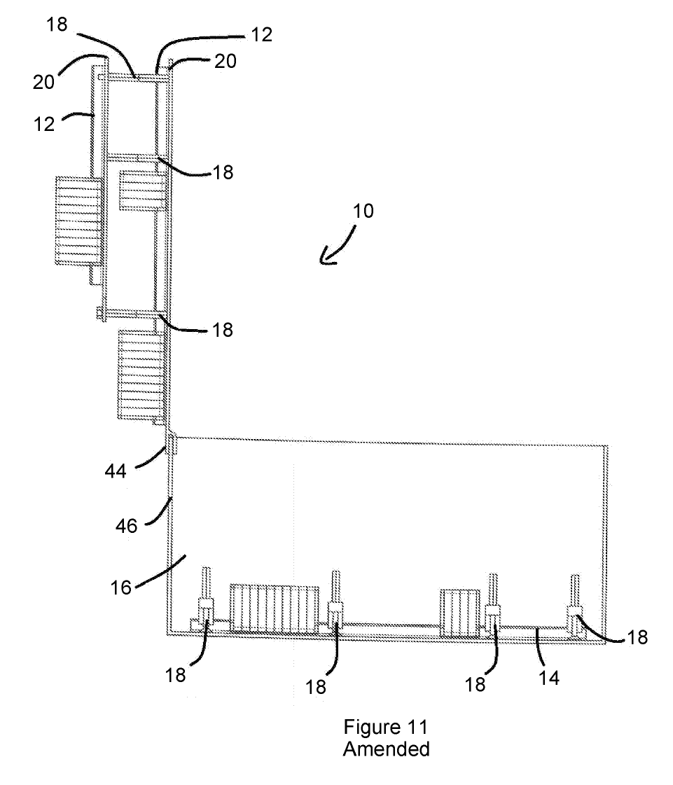

FIGS. 9-11 illustrate representative alternative embodiments of control panels 16 comprising multi-level support structures 10. In FIGS. 9 and 10, each of the first and second levels of support structures 10 comprise a hinged platform 20 of the sort generally described above. In FIG. 9A, the hinges of both the upper and lower supported platforms 20 are shown in a closed position; in FIG. 9B the hinge of the upper supported platform 20 is shown in the open position; and in FIG. 10 the hinge of the lower supported platform 20 is shown in the open position. FIG. 11 illustrates an alternative embodiment in which the upper support structure 10 comprises a hinged platform 20 as described above, and in which the platform of lower support structure 10 comprises a clip structure 44 to permit the platform to be temporarily secured to a side wall 46 of the control panel 16.

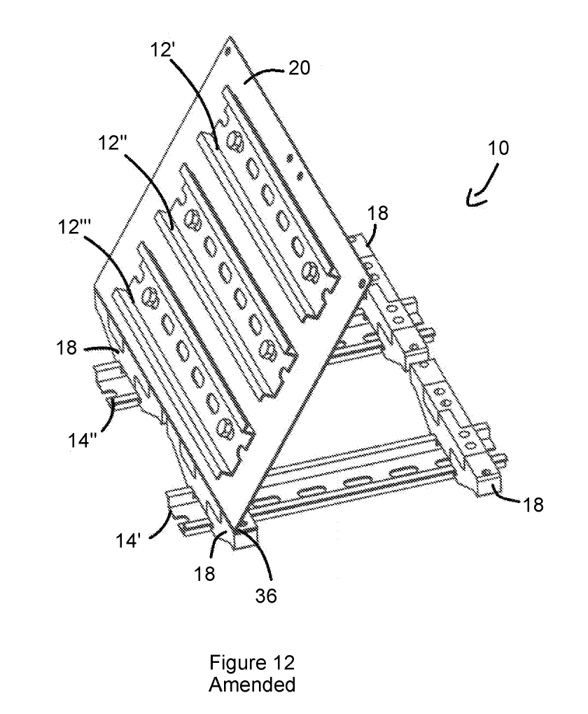

FIG. 12 illustrates a representative embodiment of a hinged support structure comprising rail mounts connected to a plurality of adjacent supporting mounting rails. In the embodiment of

FIG. 12, the support structure 10 comprises a supported platform 20 and four rail mounts 18, a first two of which are configured for connection to a first supporting rail 14′, and a second two of which are configured for connection to a second supporting rail 14″ which is adjacent and parallel to the first supporting rail 14′. Three supported rails 12′, 12″ and 12″′ are affixed to an upper surface of supported platform 20 in an orientation that is essentially perpendicular to that of the supporting rails 14′ and 14″. In a manner analogous to the embodiments of FIGS. 5-7, the supported platform 20 also comprises a hinge 36 to enable the platform 20 (including the supported rails 12′, 12″ and 12″′, as well as any electrical components affixed thereto) to be pivoted up relative to the supporting rails 14′ and 14″ to provide access thereto. As noted in the summary above, a variety of other configurations of support structures connected to a plurality of adjacent supporting rails are, of course, also contemplated, and may be desirable when accommodating unusually-shaped electronic components on either or both of the supporting and supported rails.

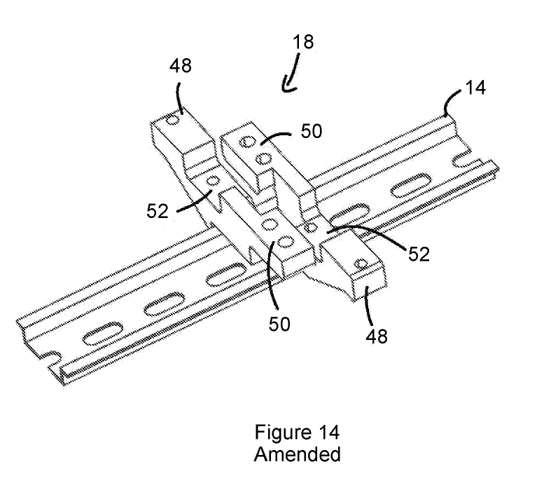

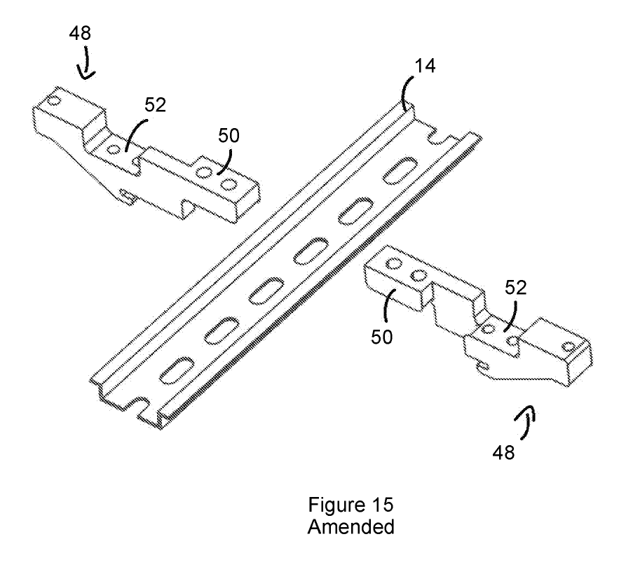

FIGS. 12-15 illustrate a representative embodiment of a longitudinally expandable rail mount 18 comprising opposing hook elements 48 configured for engagement with opposite lateral sides of a supporting rail 14, and for mating engagement with one another. Opposing hook elements 48 are identically configured, and each comprise a flange portion 50 and a corresponding recess 52, such that the flange 50 of a first hook element 48 fits within the recess 52 of the second hook element 48, and vice versa in mirror image, when the rail mount 18 is engaged on the supporting rail 14. Fasteners such as screws (not shown) may be used to lock the first and second hook elements 48 together when the rail mount 18 is in the rail-engaged position. Alternatively or additionally, various press-fit, snap-fit and other frictional engagements between opposing hook elements 48 are also possible, as would be apparent to those of skill in the art.

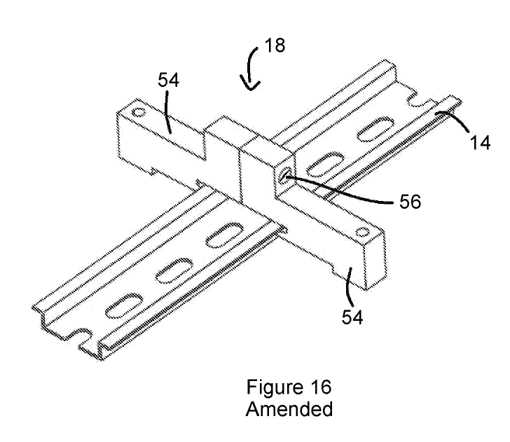

FIG. 16 illustrates a further representative embodiment of a laterally expandable rail mount 18 comprising opposing hook elements 54 configured for engagement with opposite lateral sides of a supporting rail 14, and for mating engagement with one another. A fastener such as screw 56 locks the opposing hook elements 54 together when the rail mount 18 is in the rail-engaged position.

The present description is of the best presently contemplated mode of carrying out the subject matter disclosed herein. The description is made for the purpose of illustrating the general principles of the subject matter and not to be taken in a limiting sense; the described subject matter can find utility in a variety of implementations without departing from the scope of the invention made, as will be apparent to those of skill in the art from an understanding of the principles that underlie the invention.

1. A support structure for attaching at least one supported mounting rail in spaced-apart relationship above at least one supporting mounting rail, the support structure comprising at least one rail mount configured for direct attachment to at least one supporting mounting rail.

2. The support structure of claim 1, wherein the rail mount comprises opposing hook elements configured for releasable engagement with opposite lateral sides of the supporting rail.

3. The support structure of claim 1, wherein the rail mount is non-expandable and configured for sliding engagement with the supporting rail.

4. The support structure of claim 1, wherein the rail mount is configured for frictional engagement with the supporting rail.

5. The support structure of claim 1, further comprising a supported platform situated between the at least one rail mount and the supported mounting rail.

6. The support structure of claim 5, wherein the supported platform further comprises at least one lateral flange portion.

7. The support structure of claim 5, wherein the support structure further comprises a hinge to enable the platform to be pivoted between an open and closed position.

8. The support structure of claim 5, wherein the support structure further comprises a drawer slide to enable the platform to be moved between an open and closed position.

9. An industrial enclosure comprising at least one support structure in accordance with claim 1.
